(19) United States
(12) Patent Application Publication
(10) Pub. No.: US 2012/0119315 A1
(43) Pub. Date: May 17, 2012

(54) SENSING DEVICES

(76) Inventors: Fung Suong Ou, Mountain View, CA (US); Huei Pei Kuo, Cupertino, CA (US); Zhiyong Li, Redwood City, CA (US); Min Hu, Sunnyvale, CA (US)

(21) Appl. No.: 13/384,950

(22) PCT Filed: Jan. 29, 2010
(86) PCT No.: PCT/US10/22549

§ 371 Date: Jan. 19, 2012

(51) Int. Cl. H01L 23/48; H01L 21/28; H01L 31/0224

(52) U.S. Cl. 257/431; 257/773; 438/666; 257/E31.124; 257/E23.01; 257/E21.158

(57) ABSTRACT

A sensing device (10, 10′) includes a substrate (14), and first and second electrodes (E_{IC}, E_{ICS}, E_{O}) established on the substrate (14). The first electrode (E_{IC}, E_{ICS}) has a three-dimensional shape, and the second electrode (E_{O}) is electrically isolated from and surrounds a perimeter of the first electrode (E_{IC}, E_{ICS}).

### STATEMENT REGARDING FEDERALLY SPONSORED RESEARCH OR DEVELOPMENT

This invention was made in the course of research partially supported by grants from the Defense Advanced Research Projects Agency (DARPA), Contract No. HR0011-09-3-0002. The U.S. government has certain rights in the invention.

### BACKGROUND

The present disclosure relates generally to sensing devices.

Sensing devices often incorporate nanostructures which are utilized for detecting changes in electrical and/or mechanical properties of the nanostructure when an analyte is on or near the nanostructure, or for altering optical signals emitted by an analyte when the analyte is on or near the nanostructure and is exposed to photons. Sensing devices may utilize different sensing techniques, including, for example, transduction of adsorption and/or desorption of the analytes into a readable signal, spectroscopic techniques, or other suitable techniques.

Raman spectroscopy is one useful technique for a variety of chemical or biological sensing applications. Raman spectroscopy is used to study the transitions between molecular energy states when photons interact with molecules, which results in the energy of the scattered photons being shifted. The Raman scattering of a molecule can be seen as two processes. The molecule, which is at a certain energy state, is first excited into another (either virtual or real) energy state by the incident photons, which is ordinarily in the optical frequency domain. The excited molecule then radiates as a dipole source under the influence of the environment in which it sits at a frequency that may be relatively low (i.e., Stokes scattering), or that may be relatively high (i.e., anti-Stokes scattering) compared to the excitation photons. The Raman spectrum of different molecules or matters has characteristic peaks that can be used to identify the species. Rough metal surfaces, various types of nano-antennas, as well as waveguiding structures have been used to enhance the Raman scattering processes (i.e., the excitation and/or radiation process described above). This field is generally known as surface enhanced Raman spectroscopy (SERS).

### BRIEF DESCRIPTION OF THE DRAWINGS

Features and advantages of embodiments of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1 is a flow diagram of an embodiment of a method for forming an embodiment of a sensing device;

FIGS. 2A through 2I are schematic views which together illustrate an embodiment of the method for forming an embodiment of the sensing device;

FIGS. 2A through 2F and 2J through 2L are schematic views which together illustrate an embodiment of the method for forming another embodiment of the sensing device;

FIGS. 3A through 3D are respective top views of different embodiments of a mask utilized to form different embodiments of the first electrodes in the sensing device;

FIGS. 4A and 4B are scanning electron micrographs of cone-shaped electrodes using a toroidal pattern having an outer edge-to-outer edge diameter of 100 nm (FIG. 4A) and an outer edge-to-outer edge diameter of 200 nm (FIG. 4B);

FIGS. 5A and 5B are scanning electron micrographs of cone-sphere shaped electrodes using a toroidal pattern having an outer edge-to-outer edge diameter of 100 nm (FIG. 5A) and an outer edge-to-outer edge diameter of 200 nm (FIG. 5B);

FIG. 6 is a perspective view of the embodiment of the sensing device shown in FIG. 2I;

FIG. 7 is a perspective view of another embodiment of a sensing device formed using an embodiment of the mask shown in FIG. 3A;

FIG. 8 is a perspective view of an embodiment of a sensing device formed using an embodiment of the mask shown in FIG. 3C;

FIG. 9 is a schematic cross-sectional view of an embodiment of the sensing device suitable for use as an optical sensor; and

FIG. 10 is a schematic cross-sectional view of an embodiment of the sensing device suitable for use as an electrical sensor.

### DETAILED DESCRIPTION

Embodiments of the sensing device disclosed herein include two types of electrodes (e.g., an inner electrode and a surrounding outer electrode) that are formed from/on a single substrate. This configuration advantageously enables a bias to be applied to both electrodes within a single piece of the substrate. Furthermore, the processes/methods disclosed herein for forming such sensing devices may be controlled such that the resulting inner electrode has a shape that is particularly suitable for a desired sensing application (e.g., electrical sensing or optical sensing).

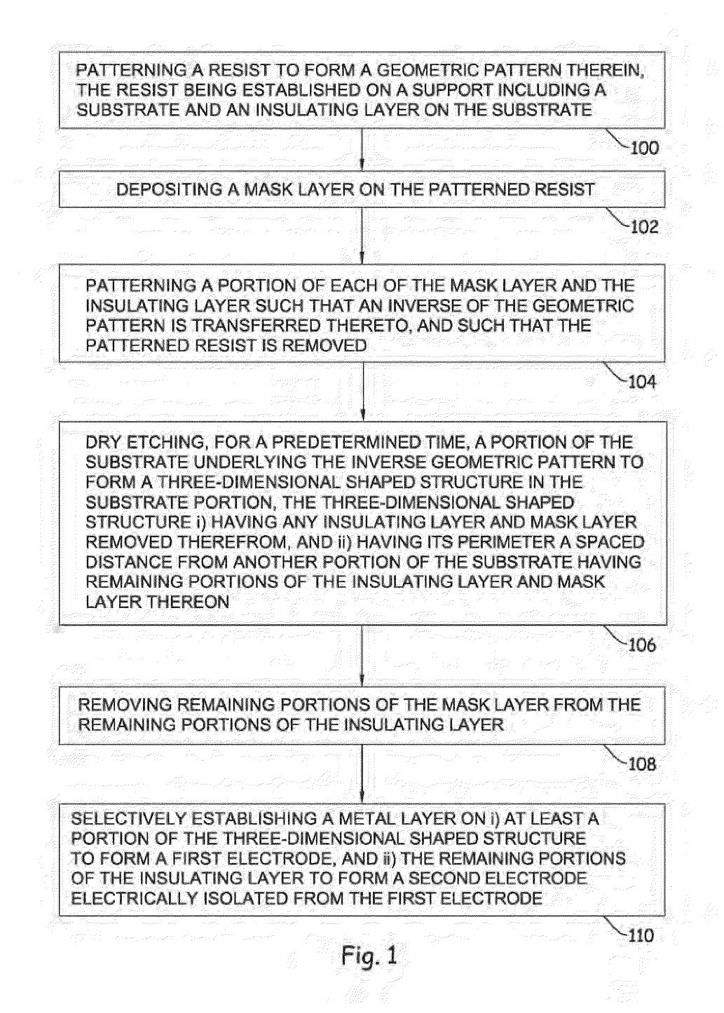

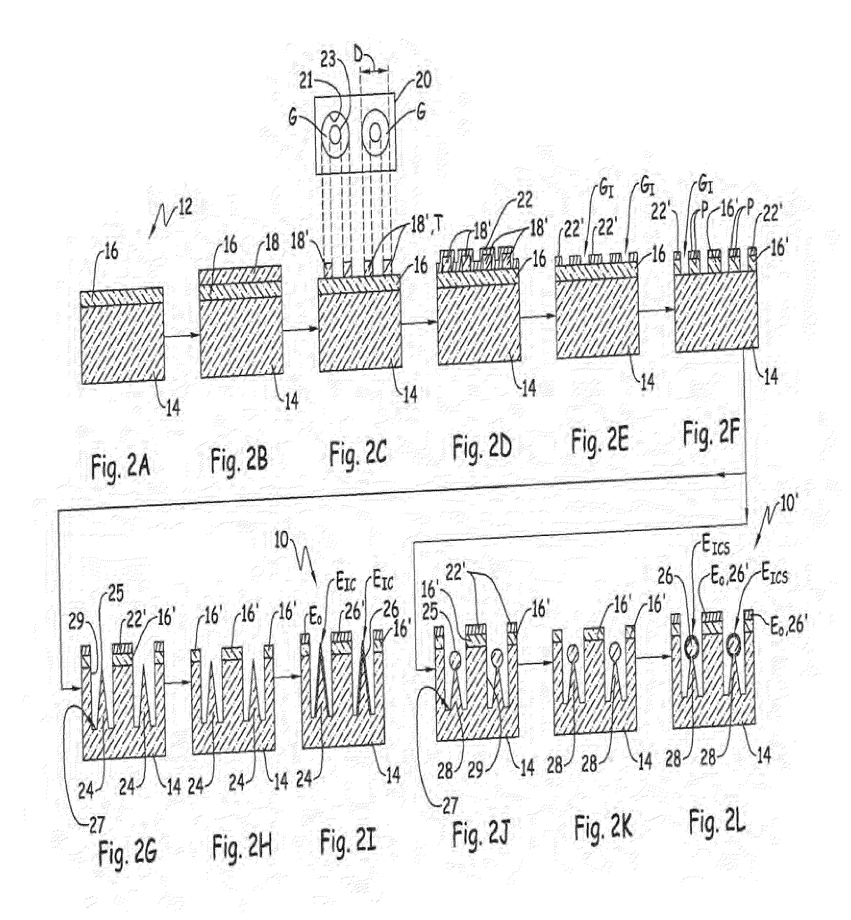

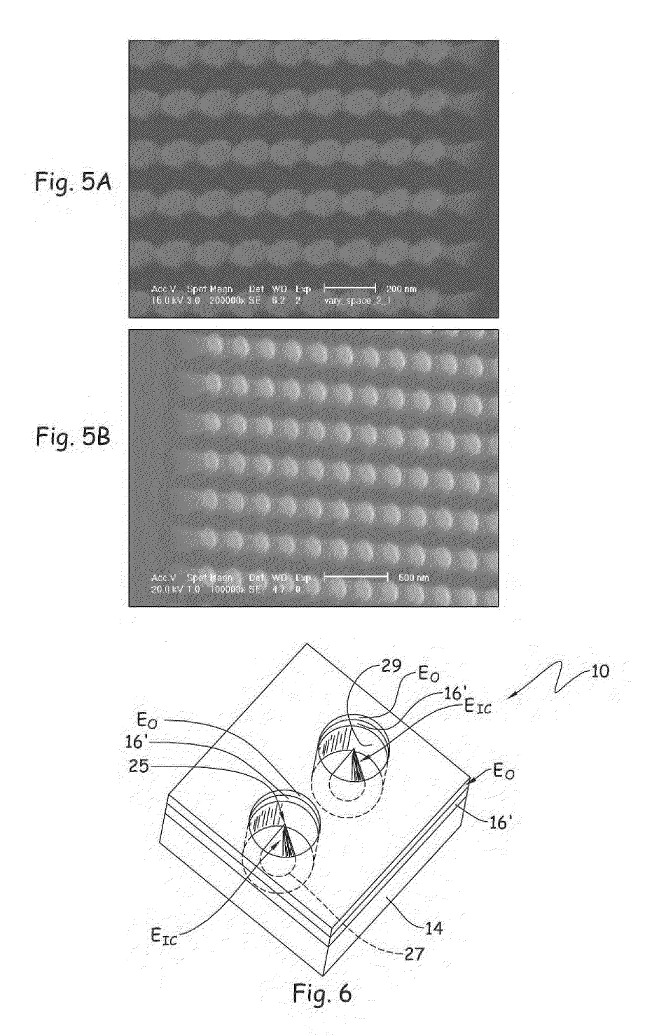

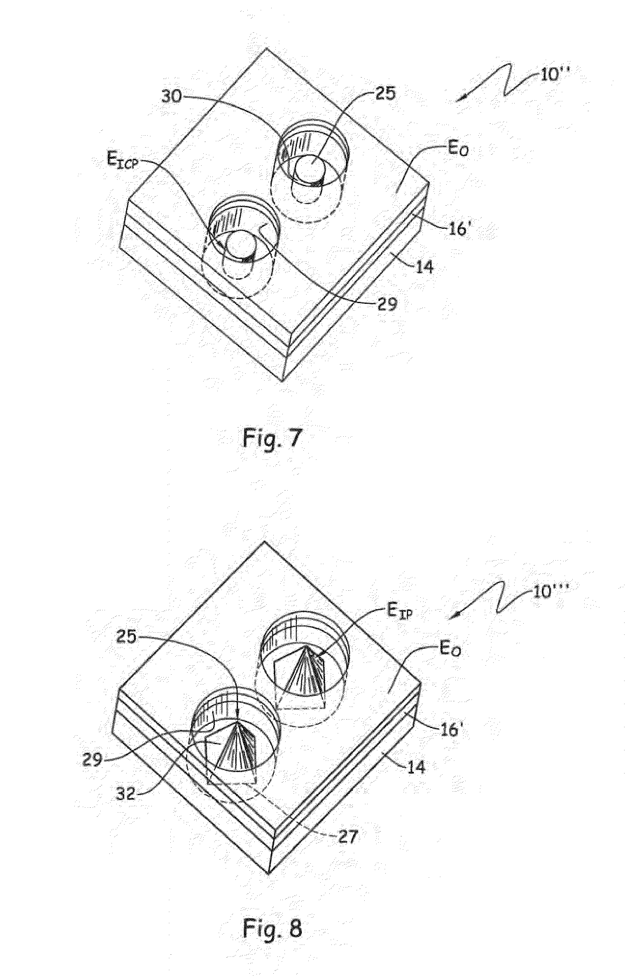

FIG. 1 illustrates an embodiment of a method for forming an embodiment of a sensing device. The steps of the method shown in FIG. 1 will be discussed in further detail herein with reference to FIGS. 2A through 2L. In particular, FIGS. 2A through 2I illustrate an embodiment of the method for forming a device including a cone-shaped electrode, and FIGS. 2A through 2F and 2J through 2L illustrate an embodiment of the method for forming a device including a cone-sphere shaped electrode. More generally, the inner electrodes are three-dimensional structures whose shape depends upon the initial geometric pattern used and the etching conditions during formation of the device. The three-dimensional shapes include cones, cone-spheres, cylinders, polygons having at least three facets that meet at a tip (e.g., a pyramid), or the like. As used herein, the terms “cone-shaped” or “cone shape” describe a protrusion having a three-dimensional geometric shape that tapers from a round perimeter base to a sharp tip (e.g., an apex or vertex). Examples of the cone-shaped electrodes are shown in FIGS. 4A and 4B (discussed further hereinbelow). Also as used herein, the terms “cone-sphere shaped” or cone-sphere shape” describe a protrusion having a three-dimensional geometric shape that tapers from a round perimeter base to a sharper portion which then extends back out into a sphere having a diameter larger than the sharper portion. Examples of the cone-sphere shaped electrodes are shown in FIGS. 5A and 5B (also discussed further hereinbelow). Still further, as used herein, the terms “polygon-shaped” or “polygon shape” describe a protrusion having three or more facets that taper from a polygon perimeter base to a sharp tip (see, e.g., FIG. 7); and the terms “cylinder-shaped” or “cylinder shape” describe a protrusion having a substantially consistent perimeter from the base to the tip (see, e.g., FIG. 8).

The embodiment of the method for forming the sensing device including the cone-shaped electrode will now be discussed in reference to FIGS. 1 and 2A through 2L. While the method illustrated in FIGS. 2A through 2L results in the formation of two inner electrodes and one continuous outer electrode, it is to be understood that a single inner electrode may be formed, or an array including three or more inner electrodes may be formed. The upper limit of how many single inner electrodes may be formed depends, at least in part, upon the size of the substrate used, the pattern used, and the fabrication process used. Generally, the embodiments disclosed herein may be scaled up as is desirable for a particular end use.

As shown in FIG. 2A, a support 12 is illustrated. The support 12 includes a substrate 14 having an insulating layer 16 established thereon. The substrate 14 is at least semi-conductive, and thus may be formed of a semiconductor or a conductor. Non-limiting examples of suitable substrate 14 materials include single crystalline silicon, silicon-on-insulators (SOI), diamond like carbon films, polymeric materials (poly(acetylene)s, poly(pyrrole)s, poly(thiophene)s, polyanilines, polythiophenes, poly(p-phenylene sulfide), and poly(para-phenylene vinylene)s (PPV), polydimethylsiloxane (PDMS), polyimides, etc.), metals (aluminum, copper, stainless steel, alloys, etc.), or other semi-conducting or conductive materials.

Any suitable insulating material may be used for the insulating layer 16. In a non-limiting example embodiment, the insulating layer 16 is an oxide (e.g., silicon dioxide). Non-limiting examples of other suitable materials for the insulating layer 16 include nitrides (e.g., silicon nitride), oxynitrides, or the like, or combinations thereof. The insulating layer 16 may be established using any suitable growth or deposition technique. A thermal oxide insulator layer may be formed by the partial oxidation of silicon (e.g., the substrate 14), which forms silicon dioxide on the silicon. Various oxide and nitride materials may be established via deposition techniques which include, but are not limited to low-pressure chemical vapor deposition (LPCVD), plasma enhanced chemical vapor deposition (PECVD), atmospheric pressure chemical vapor deposition (APCVD), or any other suitable chemical or physical vapor deposition techniques. In one embodiment, the thickness of the insulating layer is 100 nm. The thickness of the insulating layer 16 depends, at least in part, upon the voltage that will ultimately be applied to the device 10, 10′. In one embodiment, the thickness ranges from about 10 nm to about 3 μm.

FIG. 2B illustrates a resist 18 established on the insulating layer 16. A non-limiting example of a suitable resist is polymethyl methacrylate (PMMA). It is to be understood, however, that any material that can act as an electron-beam (E-beam) lithography resist may be utilized for resist 18. Further, the resist 18 may be deposited via any suitable method, such as, for example, via spin coating. In an embodiment, the thickness of the resist 18 ranges from about 10 nm to about 3 μm.

As set forth at reference numeral 100 of FIG. 1 and as illustrated in FIG. 2C, a mask 20 having one or more geometric patterns G integrally formed therein is used in conjunction with E-beam lithography to transfer the one or more geometric patterns G to the resist 18, thereby forming a patterned resist 18′. The geometric pattern G may be any shape (e.g., circle, oval, square, triangle, rectangle, pentagon, etc.) that is defined by both an outer edge 21 and an inner edge 23. It is to be understood that the area of the mask 20 between the outer and inner edges 21, 23 is the pattern G that can be transferred to another material during a lithography process. The outer and inner edges 21, 23 generally have the same shape, but the inner edge 23 is smaller than the outer edge 21. As illustrated hereinbelow, the outer edges 21 substantially dictate the shape of the wells 29 formed in the substrate 14 (see FIGS. 2G and 2J), and the inner edges 23 substantially dictate the shape of the perimeter of the base 27 of the resulting base structures 24, 28, 30, 32 (see FIGS. 2G, 2J, 7 and 8). By “substantially dictates”, it is meant that the shape of the respective edges 21, 23 matches the shape of the formed wells 29 and the bases 27, respectively, taking into account minor variations resulting from etching or other processing conditions.

The mask 20 shown in FIG. 2C (which is rotated to facilitate understanding of how the pattern G is transferred) may be used to form two toroidal shapes T in the resist 18. As such, the patterned resist 18′ itself takes on the toroid shape T. Each toroidal shape T has a desirable outer edge-to-outer edge geometry D, which may be the same or different for each shape T throughout the mask 20, depending, at least in part, on the desired largest diameter for the base structures (see, e.g., reference numerals 24 and 28 in FIGS. 2G and 2J) of the final inner electrodes (see, e.g., reference letters E_{IC} and E_{ICS} in FIGS. 2I and 2L). In one embodiment, the outer edge-to-outer edge diameter D is equal to or less than 200 nm. In another embodiment, the outer edge-to-outer edge diameter D ranges from about 100 nm to about 200 nm. In still another embodiment, the outer edge-to-outer edge diameter D ranges from about 10 nm to about 1000 nm. It is to be understood that any number or range within the stated ranges is also contemplated as being suitable for the embodiments disclosed herein. Furthermore, the numbers and ranges provided for the diameter D may also be suitable for one or more dimensions of the outer edge 21 of the other geometries (e.g., each side of the outer edge 21 of the square geometry).

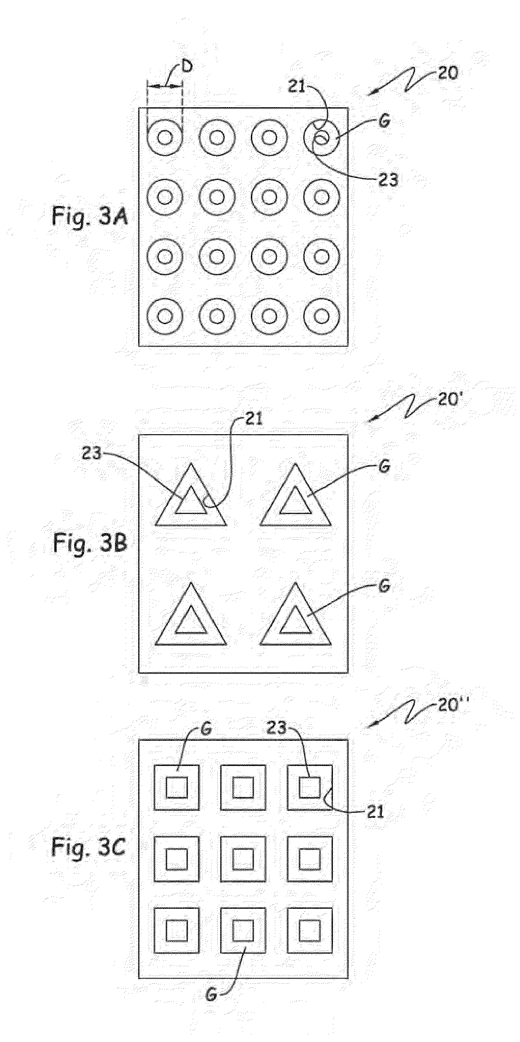

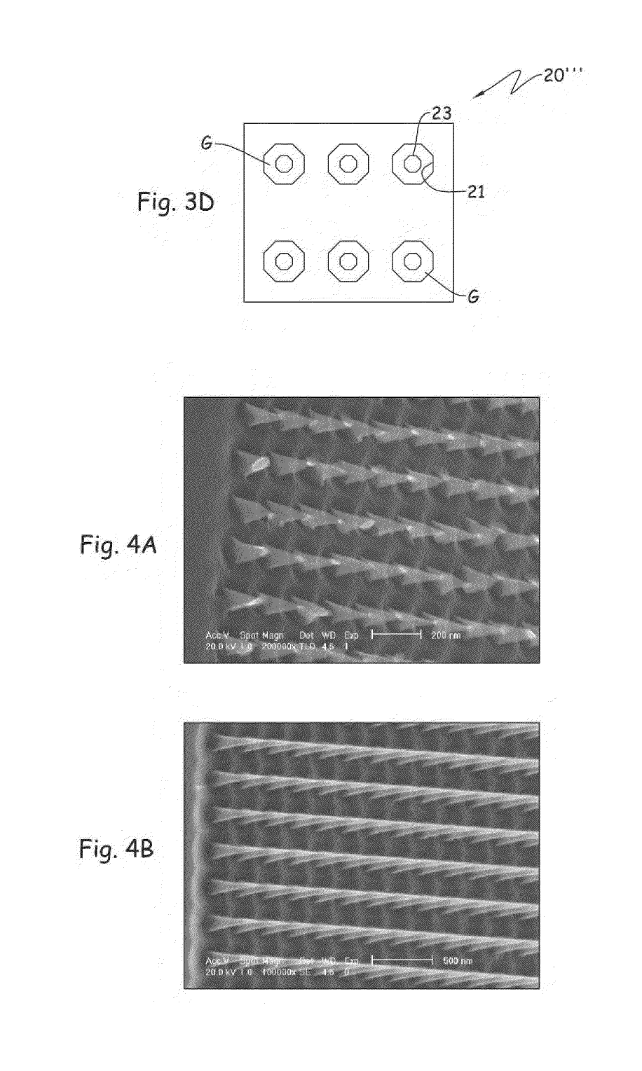

Top views of other non-limiting examples of the mask 20, 20′, 20″, 20″′ are shown in FIGS. 3A through 3D. The mask 20 shown in FIG. 3A includes a plurality of geometric patterns G having circle shaped outer and inner edges 21, 23, each of which has a particular outer edge-to-outer edge diameter D. Similar to FIG. 2C, this mask 20 will result in a plurality of toroidal shapes T formed in the resist 18 using e-beam lithography. This mask 20 may be used to form cone-shaped structures (see, e.g., FIG. 2I), cone-sphere shaped structures (see, e.g., FIG. 2L), or cylindrical shaped structures (see, e.g., FIG. 8). The mask 20′ shown in FIG. 3B includes a plurality of geometric patterns G having triangle shaped outer and inner edges 21, 23. This mask 20′ may be used to form three facet polygon shaped structures. The mask 20″ shown in FIG. 3C includes a plurality of geometric patterns G having square shaped outer and inner edges 21, 23. This mask 20″ may be used to form pyramid shaped structures (see, e.g., FIG. 7). The mask 20″′ shown in FIG. 3D includes a plurality of geometric patterns G having octagon shaped outer and inner edges 21, 23. This mask 20′″ may be used to form eight facet polygon shaped structures (not shown).

Using any of the embodiments of the mask 20, 20′, 20″, 20′″, it is to be understood that after patterning, the non-patterned portions of the resist 18 are selectively removed (as shown in FIG. 2C), thus leaving the patterned resist 18′.

Referring now to FIG. 2D and reference numeral 102 of FIG. 1, a mask layer 22 is established on the patterned resist 18′ and on exposed portions of the insulating layer 16. A non-limiting example of the mask layer 22 is chromium or any other metal. The thickness of the mask layer 22 generally ranges from about 10 nm to about 300 nm, and the mask layer 22 may be established via any suitable technique, such as sputtering, e-beam lithography, or thermal evaporation.

The established mask layer 22 may then be patterned to remove those portions of the mask layer 22 established on the patterned resist 18′, and the underlying patterned resist 18′ (see reference numeral 104 of FIG. 1 and FIG. 2E). This patterning step forms an inverse of the original geometric pattern G_{I} in the mask layer 22. The phrase “inverse of the original geometric pattern” means that the portion of the patterned layer that remains after patterning is complete does not actually take on the shape of the pattern (as does the patterned resist 18′), but rather the portion of the patterned layer that remains after patterning defines the geometric pattern G_{I} in the portion that is removed. As illustrated in FIG. 2E, the transferred or inverse geometric patterns G_{I} (in this example the toroid shapes) are actually defined by the patterned mask layer 22′ as opposed to the patterned mask layer 22′ itself taking on the geometry of the pattern. This step forms patterned mask layer 22′, and also exposes portions of the insulating layer 16.

Again referring to reference numeral 104 of FIG. 1, but now also referring to FIG. 2F, the exposed portions of the insulting layer 16 (i.e., those portions that are exposed as a result of the mask layer 22 being patterned) are now patterned. This patterning step forms an inverse of the geometric pattern G_{I} in the insulating layer 16. As illustrated in FIG. 2F, the inverse geometric pattern G_{I} is defined by both the patterned mask layer 22′ and the patterned insulating layer 16′. This step forms patterned insulating layer 16′, and also exposes portions of the substrate 14.

Both the mask layer 22 and the insulating layer 16 may be patterned via lift-off processes. While the patterning of the layers 22 and 16 is shown as a sequential process, it is to be understood that these layers 16, 22 may be patterned simultaneously.

FIG. 2G illustrates the formation of the cone-shaped three-dimensional base structure 24 of the cone-shaped inner electrode E_{IC}. As depicted at reference numeral 106, the portion of the substrate 14 underlying the inverse geometric pattern G_{I} is dry etched (e.g., via HBr etching or any other reactive ion etching process). The desired cone-shaped base structure 24 may be achieved when the geometric pattern G, G_{I} has a desirable outer edge-to-outer edge diameter D and when the etch time is controlled to correspond with the dimensions of the geometric pattern G, G_{I}. As such, the starting dimensions of the geometric pattern G dictates, at least in part, the etch time used to form the desired three-dimensional structure (in this example the cone-shaped base structure 24) in the substrate 14.

As one non-limiting example, when a 100 nm outer edge-to-outer edge diameter circular pattern is used, etching is accomplished for about 2.5 minutes to achieve the cone-shaped base structures 24. Cone-shaped base structures 24 formed using the 100 nm circular pattern and 2.5 minute etch time are shown in FIG. 4A. As another non-limiting example, when a 200 nm outer edge-to-outer edge diameter circular pattern is used, etching is accomplished for about 5 minutes to achieve the cone-shaped base structures 24. Cone-shaped base structures 24 formed using the 200 nm circular pattern and 5 minute etch time are shown in FIG. 4B. It is to be understood that the original geometric pattern G and/or the etching time may be further adjusted to alter the feature size (e.g., the diameter, height, etc.) of the cone-shaped base structures 24. In particular, the tip 25 may become smaller and smaller as etching continues. The disk-like toroidal pattern shown in this series of figures and dry etching for a predetermined time results in the formation of cone-shaped base structures 24 that are on the nano-scale (i.e., the largest diameter (at the base 27 of the structure 24) is equal to or less than 1000 nm).

As illustrated in FIG. 2G, the dry etching process forms the cone-shaped base structures 24 in a well 29 within the substrate 14 at the areas beneath the inverse geometric pattern G_{I}. As illustrated, each cone-shaped structure 24 sits within a respective well 29. During etching, the walls of the wells 29 are defined in-line with some portions of the patterned mask 22′ and are defined in the remaining un-etched substrate 14. Also during etching, other portions P (shown in FIG. 2F and removed in FIG. 2G) of the patterned insulating and mask layers 16′, 22′ are consumed. The resulting cone-shaped base structures 24 are integrally formed with other areas of the substrate 14, but are positioned within the respective wells 29 so that each is separated a spaced distance from the patterned insulating and mask layers 16′, 22′ that remain on the un-etched portions of the substrate 14. As such, the perimeter of each of the cone-shaped base structures 24 is surrounded by, but electrically isolated from, the patterned insulating and mask layers 16′, 22′.

The tips 25 of the cone-shaped base structures 24 are illustrated as being level with the surface of the substrate 14. It is to be understood, however, that the cone-shaped bases 24 can be significantly recessed from the substrate surface such that cone-shaped bases 24 in the well 29 of the substrate 14 can be formed to define a particular detection volume of gases or liquids.

Referring now to FIG. 2H and reference numeral 108 of FIG. 1, the remaining portions of the patterned mask layer 22′ are removed from the remaining portions of the patterned insulating layer 16′. This may be accomplished via any suitable selective removal process that removes the patterned mask layer 22′ without deleteriously affecting the cone-shaped base structures 24, the substrate 14, or the remaining patterned insulating layer 16. In one embodiment, the entire structure may be immersed in an etchant (e.g., a chromium etching solution) that is suitable for removal of the particular mask layer 22, 22′ material, but will not affect the other materials of the structure. This type of process results in the chemical stripping of the remaining patterned mask layer 22′ from the remaining patterned insulating layer 16′.

Reference numeral 110 of FIG. 1 and FIG. 2I illustrate the formation of the inner and outer (also referred to herein as first and second, respectively) cone-shaped electrodes E_{IC}, E_{O}. Respective metal layers 26, 26′ are selectively deposited on i) the cone-shaped base structures 24, thereby forming the inner electrodes E_{IC}, and ii) on the remaining portions of patterned insulating layer 16′, thereby forming the outer electrode E_{O}. In one embodiment, the metal layers 26, 26′ are selectively deposited on the respective desirable areas via angle metal deposition, focused ion or electron beam induced gas injection metal deposition, or laser induced metal deposition. It is to be understood however, that other selective deposition processes may be used. The metal layers 26, 26′ each have a thickness ranging from about 10 nm to about 200 nm. As illustrated in FIG. 2I, the metal layer 26 deposited on each of the cone-shaped base structures 24 is electrically isolated from the metal layer 26′ by virtue of the remaining patterned insulating layer 16′.

Generally, the metal layers 26, 26′ are each formed of a Raman active material. Suitable Raman active materials include those metals whose plasma frequency falls within the visible domain, and which are not too lossy (i.e., causing undesirable attenuation or dissipation of electrical energy). The plasma frequency depends on the density of free electrons in the metal, and corresponds to the frequency of oscillation of an electron sea if the free electrons are displaced from an equilibrium spatial distribution. Non-limiting examples of such Raman active materials include noble metals such as gold, silver, platinum, and palladium, or other metals such as copper.

Once the metals 26, 26′ are established, one embodiment of the sensing device 10 is formed. A perspective view of the device 10 of FIG. 2I is shown in FIG. 6. This view clearly illustrates that the outer electrode E_{O} is a continuous sheet of metal 26′ that has circular voids (which correspond with wells 29) formed therein. This view also clearly shows how the outer electrode E_{O} is electrically isolated from each of the inner electrodes E_{O}.

Referring now to FIGS. 1, 2A through 2F, and 2J through 2L, an embodiment of the method for forming the sensing device 10′ including the cone-sphere shaped electrode E_{ICS} will be discussed. While the method illustrated in FIGS. 2A through 2F and 2J through 2L results in the formation of two inner electrodes E_{ICS} and one continuous outer electrode E_{O}, it is again to be understood that a single inner electrode E_{ICS} may be formed, or an array including three or more inner electrodes E_{ICS} may be formed.

It is to be understood that the materials and methods described hereinabove in reference to FIG. 1 (reference numerals 100-104) and FIGS. 2A through 2F are suitable for use in this embodiment of the method, and thus will not be discussed again. To reiterate briefly, the resist 18 is patterned with the desired geometric pattern G (as shown in FIG. 2C), a mask layer 22 is deposited, and then the mask and insulting layers 22, 16 are patterned to define the inverse geometric pattern G_{I} (as shown in FIG. 2F).

Referring now to FIG. 1, reference numeral 106, and FIG. 2J, the base structure 28 of the cone-sphere shaped inner electrode E_{ICS} is formed. As depicted at reference numeral 106, the portion of the substrate 14 underlying the inverse geometric pattern G_{I} is dry etched using the technique(s) previously discussed. Similar to forming the cone-shaped base structure 24, the desired cone-sphere shaped base structure 28 may be achieved when the geometric pattern G, G_{I} has a desirable dimensions and when the etch time is controlled. In this embodiment, the starting outer edge-to-outer edge diameter D of the circular geometric pattern G (shown in FIG. 2C) and the desired final shape dictates, at least in part, the etch time used to form the respective base structures 24, 28. It is to be understood that during etching, the mask layer 22′ masks the underlying materials. This contributes to the resulting cone-sphere shaped base structure 28 formed in the well 29. Generally, a shorter etching time is utilized to form the cone-sphere shaped base structure 28 than is used to form a similarly sized cone-shaped base structure 24.

As one non-limiting example, when a 100 nm outer edge-to-outer edge diameter circular pattern is used etching is accomplished for about 1 minute to achieve the cone-sphere shaped base structures 28. Cone-sphere shaped base structures 28 formed using the 100 nm outer edge-to-outer edge diameter circular pattern and 1 minute etch time are shown in FIG. 5A. As another non-limiting example, when a 200 nm outer edge-to-outer edge diameter circular pattern is used, etching is accomplished for about 2.5 minutes to achieve the cone-sphere shaped base structures 28. Cone-sphere-shaped base structures 28 formed using the 200 nm outer edge-to-outer edge diameter circular pattern and 2.5 minute etch time are shown in FIG. 5B. It is to be understood that the original geometric pattern G and/or the etching time may be further adjusted to alter the feature size (e.g., the diameter of cone or sphere portion, height, etc.) of the cone-sphere shaped base structures 28. However, it is to be understood that etching for too long will result in the cone-shaped base structure 24 or even a flattened or cylindrical structure).

As illustrated in FIG. 2J, the dry etching process in this embodiment forms the cone-sphere shaped base structures 28 in wells 29 formed in the substrate 14 at the areas beneath the inverse geometric pattern G_{I}. During etching, the walls of the wells 29 are defined in-line with portions of the patterned mask 22′ and are defined in the remaining, un-etched substrate 14. During etching, other portions P (shown in FIG. 2F and removed in FIG. 2J) of the patterned insulating and mask layers 16′, 22′ are consumed. The resulting cone-sphere shaped base structures 28 are integrally formed with other areas of the substrate 14, but are positioned within the respective wells 29 so that each is separated a spaced distance from the patterned insulating and mask layers 16′, 22′ that remain on the un-etched portions of the substrate 14. As such, the perimeter of each of the cone-sphere shaped base structures 28 is surrounded by, but isolated from, the patterned insulating and mask layers 16′, 22′.

Referring now to FIG. 2K and reference numeral 108 of FIG. 1, the remaining portions of the patterned mask layer 22′ are removed from the remaining portions of the patterned insulating layer 16′. This may be accomplished as previously described.

Reference numeral 110 of FIG. 1 and FIG. 2L illustrate the formation of the inner and outer (also referred to herein as first and second, respectively) cone-sphere shaped electrodes E_{ICS}, E_{O}. Respective metal layers 26, 26′ (using the materials previously described) are selectively deposited (e.g., via angle metal deposition, focused ion or electron beam induced gas injection metal deposition, or laser induced metal deposition) on i) the cone-sphere shaped base structures 28, thereby forming the inner electrodes E_{ICS}, and ii) on the remaining portions of patterned insulating layer 16′, thereby forming the outer electrode E_{O}. As illustrated in FIG. 2I, the metal layer 26 deposited on each of the cone-sphere shaped bases 28 is electrically isolated from the metal layer 26′ by virtue of the remaining patterned insulating layer 16′. Once the metals 26, 26′ are established, the other embodiment of the sensing device 10′ is formed.

Referring now to FIG. 7, an example of a device 10″ including cylinder/pillar shaped inner electrodes E_{ICP} is shown. In this embodiment, the mask 20 having the circular geometric pattern G shown in FIGS. 2C and 3A may be used to form three-dimensional cylinder base structures 30. Metal 26 may be selectively deposited thereon (as previously described) to form the corresponding cylinder/pillar shaped electrodes E_{ICP} shown in FIG. 7. Such cylinder/pillar shaped base structures 30 may be formed via a method similar to that described herein in reference to FIGS. 2A through 2I, except that a more directional etching recipe is used.

Referring now to FIG. 8, an example of a device 10″′ including pyramid shaped inner electrodes E_{IP} is shown. In this embodiment, the mask 20″ having the square geometric pattern G shown in FIG. 3C may be used to form three-dimensional pyramid shaped base structures 32. The depositing and etching techniques described herein may be utilized to form the various elements of the structure 10′, and the etching conditions may be altered to achieve the desirable base structure 32. Such pyramid shaped base structures 32 have four facets which taper to form the tip 25. The base 27 of such structures 32 resembles the inner edge 23 of the square pattern G. Metal 26 may be selectively deposited thereon (as previously described) to form the corresponding pyramid shaped inner electrodes E_{IP} shown in FIG. 8.

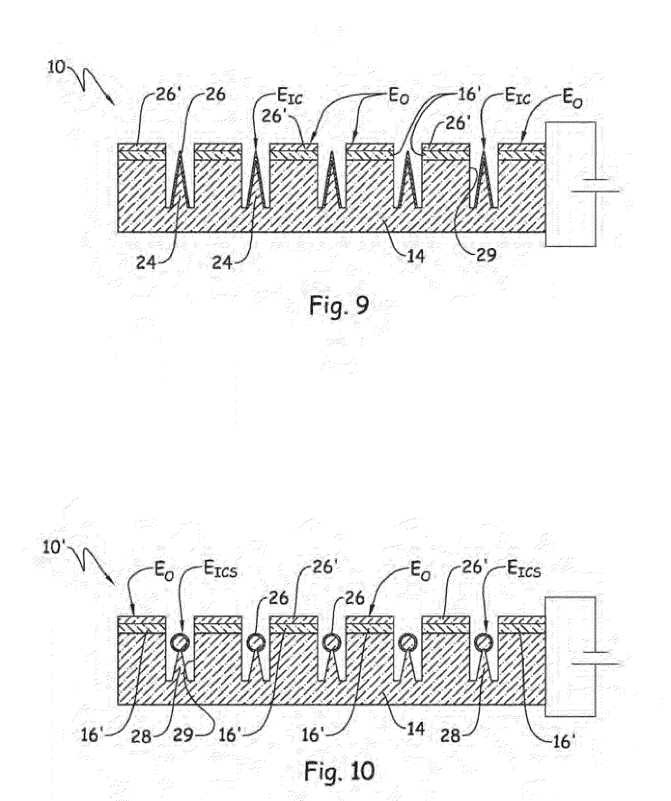

FIGS. 9 and 10 illustrate the sensing devices 10 and 10′, respectively. Each of the embodiments of the sensing devices 10, 10′ shown in these Figures includes a plurality of the respective inner electrodes E_{IC}, E_{ICS} electrically isolated from the respective single, continuous outer electrode E_{O}. Each of the Figures also illustrates a bias applied to the respective electrode E_{IC}, E_{O} and E_{ICS}, E_{O}. It is to be understood that since the substrate 14 is at least semi-conducting, it may be used to apply a bias to each of the inner electrodes E_{IC}, E_{ICS}. It is to be understood that the inner electrodes E_{ICP} and E_{IP} may also be formed in arrays.

The embodiment of the sensing device 10 shown in FIG. 9 is believed to be particularly suitable for use as an optical sensor. For example, the sensing device 10 may be used as a substrate in surface enhanced Raman spectroscopy (SERS). It is believed that under bias, the sensing device 10 will introduce an electric field modulation that will enhance SERS intensity. It is further believed that under bias, the electric field will attract more molecular species/analytes to the tip/apex of the cone-shaped electrodes E_{IC}. The increased concentration of the chemical or biological species at the tips will, in turn, enhance the SERS signal. This is especially important, for example, when a precisely defined small volume of low concentration analyte is introduced into the individual well 29. In particular, a quantitative analysis of the analyte molecules can be achieved with improved response time of the device 10 (i.e., the molecules will take less time to reach the hot spots under the electric field than the diffusion alone). A SERS system utilizing the sensing device 10 will also include a stimulation/excitation light source positioned to transmit light toward the device 10, and a detector positioned to receive the emitted SERS signals. The device 10″′ shown in FIG. 8 may also be particularly suitable as an optical sensor.

The embodiment of the sensing device 10′ shown in FIG. 10 is believed to be particularly suitable for use as an electrical sensor. The configuration of the sensing device 10′ allows bias to be applied across the electrodes E_{ICS}, E_{O}. It is believed that the high surface area provided by the sphere portion of the cone-sphere shaped electrode E_{ICS} is suitable for electrical sensing. In particular, the surface area provided by the sphere portion provides excess traps for the species under investigation. Such a structure may be advantageous when used as a gas sensor for breaking down gas molecules. The device 10″ shown in FIG. 7 may also be particularly suitable as an electrical sensor.

While several embodiments have been described in detail, it will be apparent to those skilled in the art that the disclosed embodiments may be modified. Therefore, the foregoing description is to be considered exemplary rather than limiting.

What is claimed is:

1. A sensing device (10, 10′), comprising:
a substrate (14);
a first electrode (E_{IC}, E_{ICS}) established on the substrate (14), the first electrode (E_{IC}, E_{ICS}) having a three-dimensional shape; and
a second electrode (E_{O}) established on the substrate such that the second electrode (E_{O}) is electrically isolated from and surrounds a perimeter of the first electrode (E_{IC}, E_{ICS}).

2. The sensing device (10, 10′) as defined in claim 1 wherein the three-dimensional shape is selected from a cone shape, a cone-sphere shape, a cylinder shape, and a polygonal shape having at least three facets which angle toward a tip.

3. The sensing device (10, 10′) as defined in any of claim 1 or 2 wherein the first electrode (E_{IC}, E_{ICS}) is a metal layer (26) established on a multi-layered structure including an at least semiconducting base (24, 28) and an insulating layer (16, 16′) established on the at least semiconducting base (24, 28).

4. The sensing device (10, 10′) as defined in any of claims 1 through 3 wherein the second electrode (E_{O}) is a multi-layered structure including an at least semiconducting base (14) and a metal layer (26′) established on at least a portion of the at least semiconducting base (14).

5. The sensing device (10, 10′) as defined in claims 3 and 4 wherein the substrate (14) is a semiconductor or a conductor, and wherein the at least semiconducting bases (14, 24, 28) are formed integrally with the substrate (14).

6. The sensing device (10, 10′) as defined in any of claims 1 through 5 wherein: the first electrode (E_{IC}) has a cone shape, and wherein the sensing device (10) is configured for optical sensing; or wherein the first electrode (E_{ICS}) has a cone-sphere shape, and wherein the sensing device (10′) is configured for electrical sensing.

7. The sensing device (10, 10′) as defined in any of claims 1 through 6 wherein the device (10, 10′) is configured such that a bias can be applied to a single portion of the substrate (14).

8. A sensing device (10, 10′), comprising:
a substrate (14);
an array of first electrodes (E_{IC}, E_{ICS}) established on the substrate (14), each of the first electrodes (E_{IC}, E_{ICS}) having a three-dimensional geometric shape; and
a second electrode (E_{O}) established on the substrate (14) such that the second electrode (E_{O}) is electrically isolated from each of the first electrodes (E_{IC}, E_{ICS}) and surrounds a perimeter of each of the first electrodes (E_{IC}, E_{ICS}).

9. The sensing device (10, 10′) as defined in claim 8 wherein the three-dimensional shape is selected from a cone shape, a cone-sphere shape, a cylinder shape, and a polygonal shape having at least four facets which angle toward a tip.

10. The sensing device (10, 10′) as defined in any of claim 8 or 9 wherein each of the first electrodes (E_{IC}, E_{ICS}) is a metal layer (26) established on a multi-layered structure including a first electrode semiconductor base (24, 28) and an insulating layer (16, 16′) established on the first electrode semiconductor base (24, 26); wherein the second electrode (E_{O}) is a multi-layered structure including a second electrode semiconductor base (14) and a metal layer (26′) established on at least a portion of the second electrode semiconductor base (14); wherein the substrate (14) is a semiconductor; and wherein the first and second electrode semiconductor bases (14, 24, 28) are formed integrally with the substrate (14).

11. A method of making a sensing device (10, 10′), comprising:
patterning a resist (18) to form a geometric pattern (G) therein, the geometric pattern (G) being defined by an outer edge and an inner edge and the resist (18) being established on a support (12) including a substrate (14) and an insulating layer (16) on the substrate (14);
depositing a mask layer (22) on the patterned resist (18′);
patterning a portion of each of the mask layer (22) and the insulating layer (16) such that an inverse of the geometric pattern (G_{I}) is transferred thereto, and such that the patterned resist (18′) is removed;
dry etching, for a predetermined time, a portion of the substrate (14) underlying the inverse geometric pattern (G_{I}) to form a three-dimensional structure (24, 28, 30, 32) having a perimeter shape that corresponds with a shape of the geometric pattern (G), the three-dimensional structure (24, 28, 30, 32) i) having any insulating layer (16′) and mask layer (22′) removed therefrom, and ii) having its perimeter a spaced distance from an other portion of the substrate (14) having remaining portions of the insulating layer (16′) and mask layer (22′) thereon;
removing the remaining portions of the mask layer (22′) from the remaining portions of the insulating layer (16′); and
selectively establishing a metal layer (26, 26′) on i) at least a portion of the three-dimensional structure (24, 28, 30, 32) to form a first electrode (E_{IC}, E_{ICS}), and ii) the remaining portions of the insulating layer (16′) to form a second electrode (E_{O}) electrically isolated from the first electrode (E_{IC}, E_{ICS}).

12. The method as defined in claim 11 wherein at least one dimension of the geometric pattern (G) ranges from about 100 nm to about 200 nm.

13. The method as defined in any of claim 11 or 12, further comprising controlling the predetermined time of the dry etch process to control i) a shape of the three-dimensional structure (24, 28, 30, 32), and ii) feature sizes of the three-dimensional structure (24, 28, 30, 32).

14. The method as defined in any of claims 11 through 13 wherein the patterning of the resist (18) is accomplished via electron beam lithography, and wherein patterning the portion of each of the mask layer (22) and the insulating layer (16) is accomplished via a lift-off process.

15. The method as defined in any of claims 11 through 14, further comprising:
patterning the resist (18) to form a plurality of the geometric pattern (G) therein;
patterning portions of the mask layer (22) and the insulating layer (16) such that an inverse of each of the plurality of geometric patterns (G_{I}) is transferred thereto;
dry etching, for a predetermined time, respective portions of the substrate (14) underlying the inverse geometric patterns (G_{I}) to form a plurality of three-dimensional structures (24, 28, 30, 32) in the respective substrate portions, the three-dimensional structures (24, 28, 30, 32) each i) having a perimeter shape that corresponds with a shape of the geometric pattern (G), ii) having any of the insulating layer (16′) and mask layer (22′) removed therefrom, and iii) having its perimeter a spaced distance from other portions of the substrate (14) having remaining portions of the insulating layer (16′) and mask layer (22′) thereon;
removing the remaining portions of the mask layer (22′) from the remaining portions of the insulating layer (16′); and
selectively establishing the metal layer (26, 26′) on i) at least a portion of each of the plurality of three-dimensional structures (24, 28, 30, 32) to form a plurality of first electrodes (E_{IC}, E_{ICS}), and ii) the remaining portions of the insulating layer (16′) to form the second electrode (E_{O}) electrically isolated from the plurality of first electrodes (E_{IC}, E_{ICS}).
